(19) United States
(12) Patent Application Publication
(10) Pub. No.: US 2005/0258911 A1
(43) Pub. Date: Nov. 24, 2005

(54) Ring oscillation circuit

(75) Inventors: Fujio Higuchi, Yamagata (JP); Toyoo Kondo, Yamagata (JP)

Correspondence Address: SUGHRUE MION, PLLC, 2100 PENNSYLVANIA AVENUE, N.W., SUITE 800, WASHINGTON, DC, 20037, US

(73) Assignee: NEC ELECTRONICS CORPORATION

(21) Appl. No.: 11/131,421

(22) Filed: May 18, 2005

(30) Foreign Application Priority Data
May 20, 2004 (JP) 2004-150768

(51) Int. Cl. H03B 1/00

(52) U.S. Cl. 331/57

(57) ABSTRACT

A ring oscillation circuit comprises a ring oscillator in which a plurality of inverters are connected in a ring and in which a constant current is supplied to each of the inverters, and a constant-current circuit which generates the constant current, wherein a value of the constant current is determined based on a threshold voltages of the inverters.

### BACKGROUND OF THE INVENTION

1. Field of the Invention

This invention relates to an oscillation circuit, and in particular relates to a ring oscillation circuit.

2. Description of the Related Art

Ring oscillation circuits are generally used as circuits for generating clock signals. In an ordinary ring oscillation circuit, in which an odd number of CMOS inverters are connected in a ring, the oscillation frequency changes when there are changes in temperature, or when inverter threshold voltages change due to variations arising from the manufacturing process.

In Japanese Unexamined Patent Application Publication No. 2003-283305, an example of a ring oscillation circuit which does not depend on temperature is described. The ring oscillation circuit of Japanese Unexamined Patent Application Publication No. 2003-283305 has a constant-current circuit which does not depend on temperature. A p-type transistor of the constant-current circuit is connected to a plurality of p-type transistor of inverters that are included in the ring oscillation circuit, and these p-type transistors form a current mirror. The current flowing in each of the inverters can be made substantially equal.

Whereas the above-described technology addresses changes in the oscillation frequency based on temperature, changes in oscillation frequency based on variations in inverter threshold voltages is not addressed.

### SUMMARY OF THE INVENTION

According to an aspect of the invention, a ring oscillation circuit comprises a ring oscillator in which a plurality of inverters are connected in ring and in which a constant current is supplied to each of the inverters, and a constant-current circuit which generates the constant current, wherein a value of the constant current is determined based on a threshold voltages of the inverters.

According to one aspect of the invention, a ring oscillation circuit, comprises a ring oscillator in which a plurality of inverters are connected in ring and in which a constant current is supplied to each of the inverters, and a constant-current circuit which generates the constant current. The constant-current circuit comprises a first transistor of a first conduction type, the source of which is connected to a first power supply and the gate of which is connected to the drain, a second transistor of a second conduction type, connected between the drain of the first transistor and a second power supply, a third transistor of the first conduction type, the gate of which is connected to the drain of the first transistor, and the source of which is connected to the first power supply, a fourth transistor of the second conduction type, the drain and gate of which are connected to the drain of the third transistor and to the gate of the second transistor, and a fifth transistor of the second conduction type, the drain and gate of which are connected to the source of the fourth transistor, and the source of which is connected to the second power supply.

According to another aspect of the invention, a ring oscillation circuit comprises a ring oscillator in which a plurality of inverters are connected in a ring and in which a constant current is supplied to each of the inverters and a constant-current circuit which generates the constant current. The constant-current circuit comprises a first transistor of a first conduction type, the source of which is connected to a first power supply and the gate of which is connected to the drain, a second transistor of a second conduction type, the source of which is connected via a resistance to a second power supply and the drain of which is connected to the drain of the first transistor, a third transistor of the first conduction type, the gate of which is connected to the drain of the first transistor and the source of which is connected to the first power supply, and a fourth transistor of the second conduction type, the source of which is connected to the second power supply, the gate of which is connected to a node between the source of the second transistor and the resistance, and the drain of which is connected to the drain of the third transistor and to the gate of the second transistor.

### BRIEF DESCRIPTION OF THE DRAWINGS

The above and other objects, advantages and features of the present invention will be more apparent from the following description taken in conjunction with the accompanying drawings, in which:

FIG. 1 is a circuit diagram of Aspect 1 of the invention;

FIG. 2 shows the output waveform of the ring oscillator of Aspect 1;

FIG. 3 shows the current of the constant-current circuit, as a function of variations in the threshold voltage Vth;

FIG. 4A shows fluctuations in the period with variations in the threshold voltage Vth in the conventional ring oscillation circuit;

FIG. 4B shows fluctuations in the period with variations in the threshold voltage Vth in the embodiment;

FIG. 5 is a circuit diagram of the second embodiment of the invention; and, FIG. 6 shows the output waveform of a ring oscillator circuit of this invention.

### DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposed.

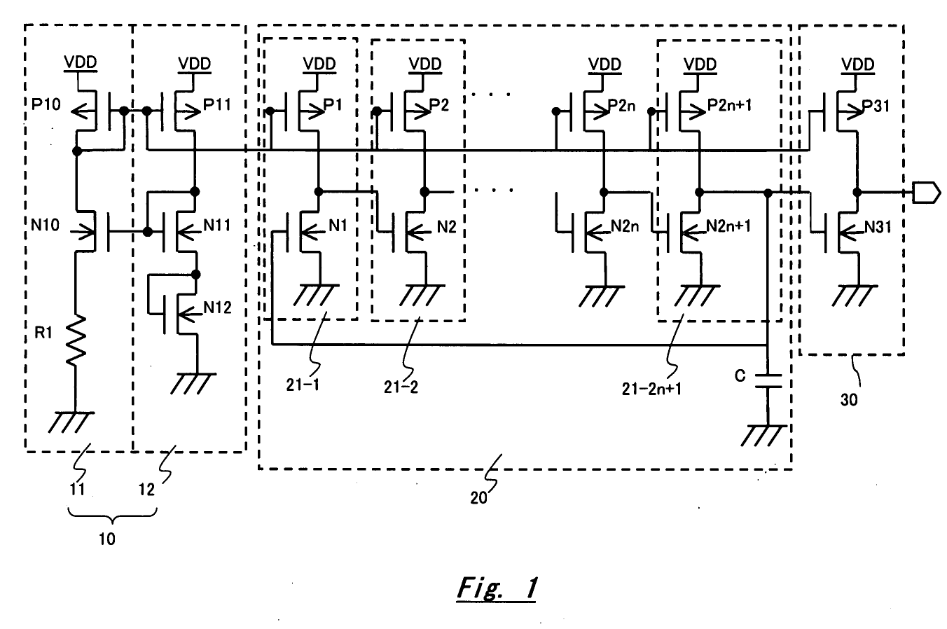

Embodiments of the invention are explained in detail, referring to the drawings. FIG. 1 is a circuit diagram of the ring oscillation circuit of a first embodiment. The ring oscillation circuit of the first embodiment has a constant-current circuit 10, ring oscillator 20, and waveform adjusting circuit 30.

As shown in FIG. 1, the constant-current circuit 10 comprises a first current source 11 and a second current source 12. The first current source 11 has a first conduction type PMOS transistor P10, a second conduction type NMOS transistor N10, and a bias voltage generator resistance R1.

The source of the PMOS transistor P10 is connected to the power supply voltage VDD, which is a first power supply, and the gate and drain of the PMOS transistor P10 are connected with each other. The drain of the NMOS transistor N10 is connected to the drain of the PMOS transistor P10, and the source is connected to ground potential (GND), which is a second power supply, via resistance R1. Thus in the first current source 11, the PMOS transistor P10, NMOS transistor N10, and resistance R1 are connected in series between the first power supply and second power supply.

The second current source 12 has a PMOS transistor P11, NMOS transistor N11, and NMOS transistor N12.

The source of the PMOS transistor P11 is connected to the power supply voltage VDD, and the drain is connected to the drain of the NMOS transistor N11. The source of the NMOS transistor N11 is connected to the drain of the NMOS transistor N12. The gate and drain of the NMOS transistor N12 are connected with each other, and the source is connected to ground potential (GND). Thus in the second current source 12, the PMOS transistor P11 and the NMOS transistors N11 and N12 are connected in series between the first and second power supplies.

The gate of the PMOS transistor P11 of the second current source 12 is connected to the gate of the PMOS transistor P10 of the first current source 11. The gate and drain of the NMOS transistor N11 are connected to the gate of the NMOS transistor N10 of the first current source 11. By means of these connections, a current mirror is formed. A current substantially equal to the current flowing in the first current source 11 flows in the second current source.

The ring oscillator 20 is a ring oscillator in which an odd number (2n+1, where n is a natural number) of inverters 21-1 to 21-2n+1 are connected in a ring. Each of the inverters 21 has a PMOS transistor and an NMOS transistor. The PMOS transistor and NMOS transistor within each of the inverters 21 are connected in series between the first power supply (VDD) and the second power supply (GND). Below, these connections are described in detail, referring to FIG. 1.

In the ring oscillator, the source of the PMOS transistor P1 comprised by the first inverter 21-1 is connected to the first power supply VDD. The gate of PMOS transistor P1 is connected to the gate of the PMOS transistor P10 of the constant-current circuit 10, forming a current mirror. The drain terminal of the NMOS transistor N1 is connected to the drain of the p-type transistor P1, and the source is connected to the second power supply (GND).

The source of the PMOS transistor P2 included in the second inverter 21-2 is connected to VDD, and similarly to the first inverter, the gate is connected to the gate of the PMOS transistor P10. The drain of the NMOS transistor N2 is connected to the drain of the PMOS transistor P2, and the source is connected to ground. The gate of the NMOS transistor N2 is connected to the output of the first inverter, that is, to the drain of the PMOS transistor P1 and to the drain of the NMOS transistor N1. The voltage applied to the gate of the NMOS transistor is equivalent to the input signal for each inverter.

Though not shown, in the third inverter similarly, the gate of the PMOS transistor P3 is connected to the constant-current circuit 10, and the gate of the NMOS transistor N3, which is the input for the third inverter, is connected to the output of the second inverter. By repeating inverters configured in this manner for 2n+1 times, a ring oscillator 20 is obtained. The output terminal of the 2n+1th inverter 21-2n+1, that is, the drain of the PMOS transistor P2n+1 and the drain of the NMOS transistor N2n+1, is connected to the gate of the NMOS transistor N1 comprised by the first inverter. Thus the output of the final inverter (the 2n+1th inverter) is connected to the input of the gate of the NMOS transistor N1 in the first inverter, to form a ring oscillation circuit. The output of the final inverter 21-2n+1 is the output terminal of the ring oscillator 20.

As shown in FIG. 1, a capacitor C is connected between the output terminal of the ring oscillator 20 and ground (GND). This capacitor C is provided to adjust the oscillation frequency of the ring oscillator 20. Oscillation action results from the repeated charging, via the PMOS transistor P2n+1, and discharging, via the NMOS transistor N2n+1, of this capacitor C.

The waveform adjusting circuit 30 comprises at least one inverter. As shown in FIG. 1, the source of the PMOS transistor P31 comprised by the inverter is connected to VDD. The gate of the PMOS transistor P31 is connected to the gate of the PMOS transistor P10 of the constant-current circuit 10, forming a current mirror. On the other hand, the drain terminal of the NMOS transistor N31 is connected to the drain of the p-type transistor P31, and the source is connected to ground. The gate of the NMOS transistor N31 is connected to the output terminal of the ring oscillator 20. The output of the final inverter of the waveform adjusting circuit 30 is the output of the ring oscillation circuit of the first embodiment. In the circuit shown in FIG. 1, only one inverter for waveform adjusting is shown. Hence the point at which the drain of the PMOS transistor P31 and the drain of the NMOS transistor N31 are connected is the output terminal of the ring oscillation circuit.

The NMOS transistor N12 in the above-described constant-current circuit 10 and the NMOS transistors N1 to N2n+1 in the inverters 21-1 to 21-2n+1 are transistors manufactured using the same device processes. As explained above, the first current source 11 and second current source 12 form a current mirror. Hence the current flowing in the PMOS transistor P10, NMOS transistor N10 and bias voltage generation resistance R1 of the first current source 11 is substantially equal to the current flowing in the PMOS transistor P11 and NMOS transistors N11 and N12 of the second current source 12. The plurality of PMOS transistors P1 to P2n+1 of the ring oscillator 20 are also connected in a current-mirror structure with the first current source 11 of the constant-current supply 10, so that a similar current flows in the PMOS transistors P1 to P2n+1.

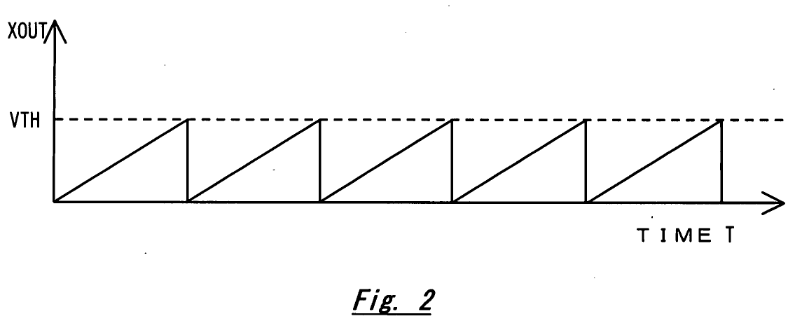

FIG. 2 shows the waveform of the output voltage (XOUT) at the output terminal of the ring oscillator 20 in the ring oscillation circuit described above. Below, operation of the ring oscillator 20 is explained using FIG. 2. The capacitor C connected to the output terminal of the ring oscillator 20 is gradually charged by the current flowing via the PMOS transistor P2n+1. When the charge of the capacitor C reaches the threshold voltage VTH of the inverter 21, the NMOS transistor N1 connected to the output terminal is turned on. As a result, the output of the first inverter 21-1 goes to L level, and the NMOS transistor N2 of the second inverter 21-2 is turned off. The NMOS transistor N3 of the third inverter is then turned on, the NMOS transistor of the fourth inverter is turned off, and this operation is repeated according to the number of the inverters 21, so that by turning on the NMOS transistor N2n+1, the capacitance C is discharged. With the discharge of this capacitance C, the NMOS transistor of the first inverter 21-1 is turned off, and operation opposite that described above is repeated, until the NMOS transistor N2n+1 is turned off, and charging of the capacitance C is begun again. Through repetition of this operation, the ring oscillator 20 oscillates at a prescribed frequency.

Here, the threshold voltage VTH of the inverters 21 is a voltage determined by the voltage that the current of the PMOS transistor and the current of the NMOS transistor is reversed. As explained above, a current flows in the PMOS transistors of the inverters based on the constant-current circuit 10. When the value of this constant current is small, the threshold VTH of the inverters 21 is a voltage determined substantially by the threshold voltage Vth of the NMOS transistor. That is, the oscillation frequency is determined according to the time required for the capacitance C to be charged to the threshold Vth of the NMOS transistor N1 by the current flowing in the PMOS transistors of the inverters (the current generated by the constant-current circuit 10). Hereafter, the inverter threshold VTH is explained primarily in terms of the thresholds Vth of NMOS transistors in the inverters 21, and for purposes of simplification the thresholds of PMOS transistors are not considered.

Here, operation of the constant-current circuit 10 in a case in which fluctuations occur in the threshold voltage Vth of the NMOS transistors of the inverters 21 due to variations in manufacturing processes and other causes is explained in detail. The value of the constant current flowing in the first current source 11 is determined primarily by the value of the resistance R1 for bias voltage generation. However, the drain voltage of the NMOS transistor N11 is applied to the gate of the NMOS transistor N10 of the first current source 11. Therefore, changes in the voltage at the drain of NMOS transistor N11 cause changes in the gate voltage of the NMOS transistor N10, and the constant current generated by the first current source 11 also changes. If the voltage applied to the gate of the NMOS transistor N10 is VG_{N10}, and the thresholds of the NMOS transistors N11 and N12 are respectively Vth_{N11}, Vth_{N12}, then
VG_{N10}=Vth_{N11}+Vth_{N12}

As explained above, the NMOS transistor N12 of the second current source 12 is a transistor fabricated using the same processes as the NMOS transistors N1 to N2n+1 in the ring oscillator 20. Hence if for example the threshold voltages Vth of the NMOS transistors N1 to N2n+1 in the inverters 21 were high due to variations in manufacturing processes, the threshold VthNl2 of the NMOS transistor N12 would also be high. If on the other hand the thresholds Vth of the NMOS transistors N1 to N2n+1 were low, then the threshold Vth_{N12} of the NMOS transistor N12 would also be low. Therefore, if in the above equation Vth_{N11} is constant, then the voltage applied to the gate of the NMOS transistor N10 fluctuates according to changes in the threshold of the NMOS transistor N12. The threshold Vth_{N12} of the NMOS transistor N12 is based on fluctuations in the thresholds Vth of the NMOS transistors N1 to N2n+1 of the inverters 21, so that if Vth values are high the gate voltage VG_{N10} of the NMOS transistor N10 is also high as a consequence, and when Vth values are low, VG_{N10} is also low.

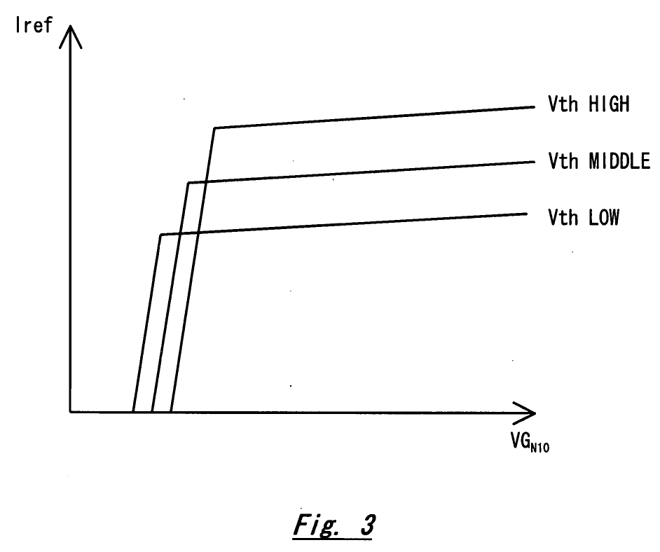

FIG. 3 shows the relationship between the voltage applied to the gate of the NMOS transistor N10 of the first current source 11 and the current Iref flowing in the first current source 11, when the thresholds Vth of the NMOS transistors in the ring oscillator change. When the thresholds Vth of the NMOS transistors N1 to N2n+1 of the inverters 21 are high, the threshold Vth_{N12} of the NMOS transistor N12 is also high. Because, in accordance with the above equation, the voltage VG_{N10} applied to the gate of NMOS transistor N10 is also high, the saturation value of the current flowing in the NMOS transistor N10 is increased, as shown in FIG. 3. As a result, the output current Iref of the first current source 11 is also increased (see FIG. 3).

On the other hand, when the thresholds of the NMOS transistors N1 to N2n+1 are low, the voltage applied to the gate of NMOS transistor N10 is also low. Consequently the saturation value of current flowing in NMOS transistor N10 is also reduced. As a result, the output current Iref of first current source 11 is decreased (see FIG. 3). Because the current in each of the inverters 21 is determined based on the current Iref flowing in the first current source 11, this current value is equivalent to the output current of the constant-current circuit 10.

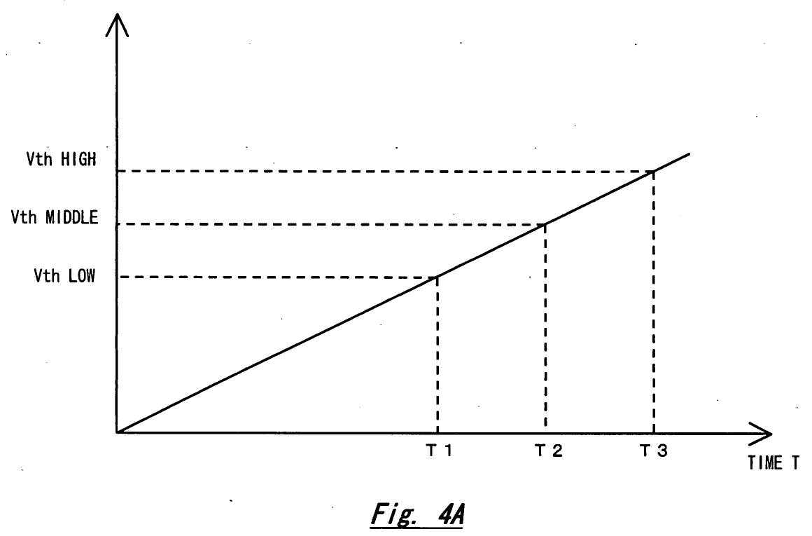

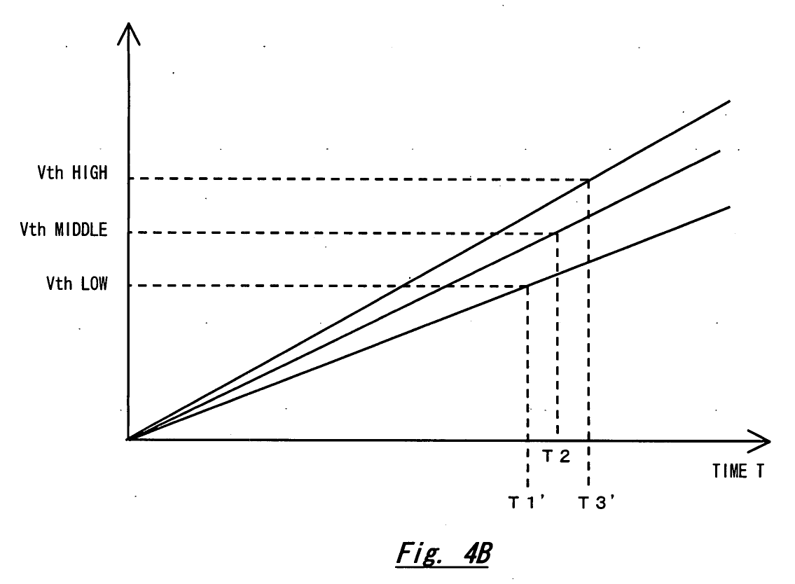

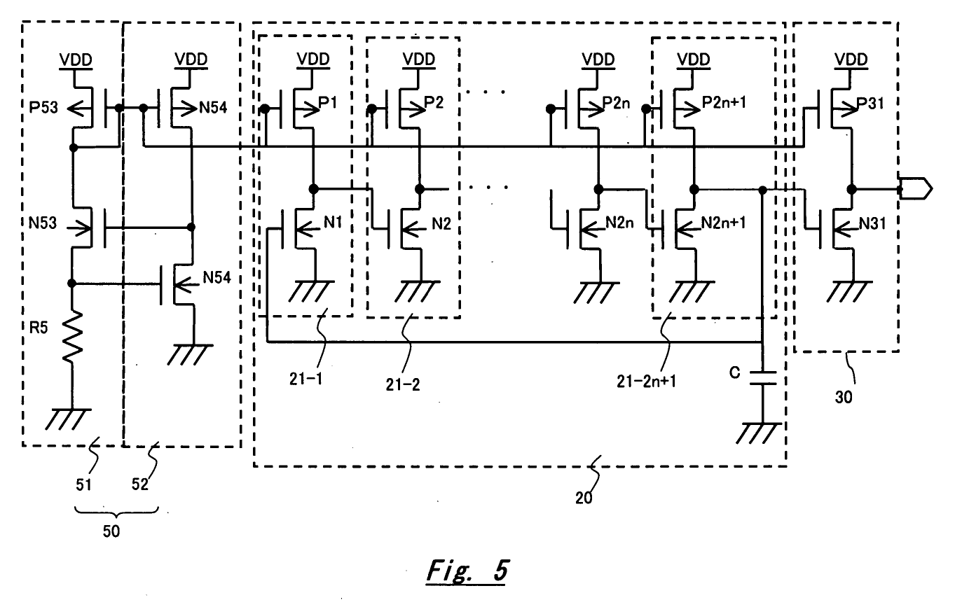

FIG. 4A and FIG. 4B show the times required for a conventional ring oscillation circuit and for the ring oscillation circuit of the first embodiment, having a constant-current circuit 10 as described above, to charge capacitance C to the inverter threshold Vth. This time corresponds to the period of the oscillation frequency at which the ring oscillation circuit operates.

As shown in FIG. 4A, in a conventional ring oscillation circuit, the value of current which charges the capacitance C is always constant, regardless of variations in inverter thresholds. Hence when the thresholds Vth of inverters are high due to variations of manufacturing, the period from time T0 to time T3 is longer than the period from time T0 to time T2. Time T0 is the time when charging is begun. Time T3 is the time when the voltage of capacitor C reaches Vth, and the output of the inverter 21 is inverted. Time T2 is the time which corresponds to the target period.

On the other hand, when the inverter thresholds Vth are low, the period from time T0 to time T1 is shorter than the period from time T0 to time T2. Time T1 is the time when the voltage of capacitor C reaches Vth, and the output of the inverter 21 is inverted.

In contrast, in the ring oscillation circuit of the first embodiment, when the inverter thresholds Vth are high the constant current Iref generated by the constant-current circuit 10 is also large. The capacitance C is charged by a larger current, so that as shown in FIG. 4B the time T3′ at which the voltage of capacitor C reaches Vth is earlier than the time T3 for the conventional circuit when the Vth is high. The voltage of capacitor C reaches Vth at time T3′ closer to the target time T2. Then the outputs of the inverters 21 are inverted, and as already explained, oscillation operation is continued.

On the other hand, when the inverter thresholds Vth are low the constant current Iref generated by the constant-current circuit 10 is also small. Because the capacitance C is charged by a smaller current, as shown in FIG. 4B, the time T1′ at which the voltage of capacitor C reaches Vth is later than the time T1 for the conventional circuit when Vth is low. The voltage of capacitor C reaches Vth at a time T1′ closer to the target time T2.

That is, in the ring oscillation circuit of the first embodiment the current flowing in inverters 21 within the ring oscillator 20 is changed according to variations in the threshold voltage Vth of the inverter NMOS transistors in the ring oscillator, so that the period is stabilized and fluctuations in the oscillation frequency due to manufacturing variations can be suppressed. Specifically, a transistor (NMOS transistor N12) manufactured using the same processes as the inverter transistors in the ring oscillator 20, having a threshold corresponding to the thresholds of the transistors in the ring oscillator 20, is positioned in the constant-current circuit 10. Because this constant-current circuit 10 generates a constant current based on the threshold voltage of the NMOS transistor N12, even in cases where there is fluctuation in transistor thresholds due to variations in manufacturing processes or similar, a stabilized oscillation frequency can be obtained.

The signal output by the ring oscillator 20 has a shape close to that of a triangular wave, as shown in FIG. 2, but the waveform is shaped in the inverter within the waveform adjusting circuit 30, so that an output waveform OUT with a large-amplitude pulse shape, shown in FIG. 6, is output to the next-stage circuit.

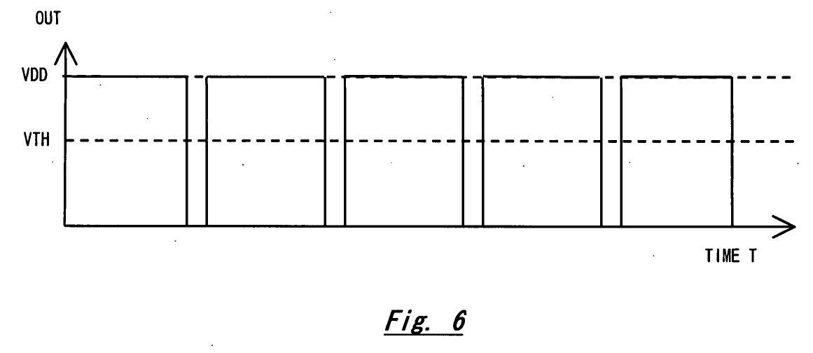

FIG. 5 is a circuit diagram showing the ring oscillation circuit of a second embodiment of the invention. Similarly to the first embodiment, this ring oscillation circuit has a constant-current circuit 50, ring oscillator 20, and waveform adjusting circuit 30. The ring oscillation circuit of the second embodiment has a constant-current circuit 50 configured differently from that in the first embodiment. Because the structures of the ring oscillator 20 and waveform adjusting circuit 30 are the same, detailed explanations are omitted.

The constant-current circuit 50 in the second embodiment has a first current source 51 and second current source 52. The first current source 51 has a first conduction type PMOS transistor P53, a second conduction type NMOS transistor N53, and a bias voltage generation resistance R5.

The source of the PMOS transistor P53 is connected to the power supply voltage VDD which is the first power supply, and the gate and drain are connected. The drain of the NMOS transistor N53 is connected to the drain of the PMOS transistor P53, and the source is connected, through the resistance R1, to ground potential (GND) which is the second power supply. Thus in the first current source 51 the PMOS transistor P53, NMOS transistor N53, and resistance R5 are connected in series between the first and second power supplies.

The second current source 52 has a PMOS transistor P54, which is a third transistor of the first conduction type, and an NMOS transistor N54 which is a fourth transistor of the second conduction type.

The source of the PMOS transistor P54 is connected to the power supply voltage VDD, and the drain is connected to the drain of the NMOS transistor N54. The source of the NMOS transistor N54 is connected to ground potential (GND). Thus in the second current source 12, the PMOS transistor P54 and NMOS transistor N54 are connected in series between the first and second power supplies.

The gate of the PMOS transistor P54 in the second current source 52 is connected to the gate of the PMOS transistor P54 of the first current source 51. By means of this connection, a current mirror is configured. The gate of the NMOS transistor N53 is connected to the drain of the NMOS transistor N54, and the gate of the NMOS transistor N54 is connected to a node between the source of the NMOS transistor N53 and the resistance R5. Here the NMOS transistor N54 of the second current source 52 is a transistor manufactured using the same processes as the NMOS transistors N1 to N2n+1 of the inverters 21, and similarly to the first embodiment, has a threshold voltage Vth_{N54} which reflects the variations in the Vth of the NMOS transistors of the inverters 21 at the time of manufacture. The constant current generated by such a constant-current circuit 50 based on variations in the threshold voltages of transistors in the inverters 21 is explained below.

As stated above, in the second current source 52, the gate of the NMOS transistor N54 is connected to a node between the source of the NMOS transistor N53 and the resistance R5. Here the voltage drop across the resistance in the first current source 51 is large compared with fluctuations in voltage due to the operation of the other PMOS transistor P53 and NMOS transistor N53, so that the voltage applied to the gate of the NMOS transistor N54 can be regarded as constant. In such a case, a saturation current flows essentially flows in the NMOS transistor N54 based on the threshold Vth_{N54} of the NMOS transistor N54. The relation between this threshold Vth_{N54} and the saturation current is such that as the threshold Vth_{N54} rises the current flowing in the NMOS transistor N54 also increases, and if the threshold Vth_{N54} is low the current flowing in the NMOS transistor N54 is also small. That is, based on changes in the threshold Vth_{N54} of the NMOS transistor N54, the voltage drop due to NMOS transistor N54 fluctuates. In other words, the larger the current flowing in NMOS transistor N54, the greater is the voltage drop due to the NMOS transistor.

The gate of NMOS transistor N53 is connected to the drain of NMOS transistor N54. That is, the larger the voltage drop due to NMOS transistor N54, the larger is the voltage applied to the gate of NMOS transistor N53, and the smaller the voltage drop due to NMOS transistor N54, the smaller is the voltage applied to the gate of NMOS transistor N53.

As explained above, the current flowing in the NMOS transistor N54 is determined based on the threshold Vth_{N54} thereof. Because this NMOS transistor N54 is a transistor manufactured using the same processes as for NMOS transistors in the inverters 21, the threshold VthN54 reflects fluctuations in the thresholds Vth.

As a result, similarly to the first embodiment, when the thresholds of the NMOS transistors of the inverters 21 are high a high voltage is applied to the gate of NMOS transistor N53, so that the current generated by the constant-current circuit 50 is large. When the thresholds of the NMOS transistors of the inverters 21 are low, a low voltage is applied to the gate of NMOS transistor N53, so that the current generated by the constant-current circuit 50 is small.

Thus based on fluctuations in the Vth values of NMOS transistors in the inverters 21, the current changes similarly to the change in the first embodiment, so that as in the first embodiment the period is stabilized, and fluctuations in the oscillation frequency due to variations in threshold voltages can be suppressed.

Further, in the constant-current circuit 50 of the second embodiment the gate of NMOS transistor N54 is connected to a node between NMOS transistor N53 and resistance R5, so that the NMOS transistor N12 of the first embodiment can be omitted while obtaining similar advantageous results. The number of transistor used to adjust the current of the constant-current circuit connected between the first power supply (VDD) and the second power supply (GND) is reduced, so that even when the first power supply voltage is reduced, the advantageous results of this invention can be obtained.

As explained in detail above, by means of the embodiments of this invention, even when there are changes in the threshold voltages of inverters in the ring oscillator due to manufacturing variations, and more specifically changes in the threshold voltages of the NMOS transistors, the value of the constant current generated by the constant-current voltage is changed according to fluctuations in threshold voltages. By this means, fluctuations in the period of the oscillation frequency due to changes in transistor threshold voltages can be prevented, and a ring oscillation circuit with a stabilized frequency can be obtained.

According to a still more detailed configuration of this invention, transistors (N12, N54) which reflect fluctuations in the threshold voltages in ring oscillator inverters are provided in the constant-current circuit. Because the constant current generated by the constant-current circuit is determined based on the threshold voltages of these transistors, a stabilized oscillation frequency can be obtained even when there is fluctuation of the threshold voltages in the inverters 21. Further, these transistors (N12, N54) are manufactured by the same processes used for the NMOS transistors N1 to N2n+1 of the inverters, and so are transistors which accurately reflect fluctuations in the threshold voltages of the NMOS transistors N1 to N2n+1. Consequently a ring oscillation circuit can be obtained with minimal fluctuation of the oscillation frequency due to manufacturing variations.

It is apparent that the present invention is not limited to the above embodiment and it may be modified and changed without departing from the scope and spirit of the invention.

1. A ring oscillation circuit comprising:
a ring oscillator in which a plurality of inverters are connected in a ring, and in which a constant current is supplied to each of the inverters; and,
a constant-current circuit which generates the constant current;
wherein a value of the constant current is determined based on a threshold voltages of the inverters.

2. The ring oscillation circuit according to claim 1, wherein each of the inverters comprises a first transistor of a first conduction type and a second transistor of a second conduction type, the constant-current circuit comprises a third transistor of the second conduction type, and the constant-current circuit determines the value of the generated constant current based on a threshold voltage of the third transistor.

3. The ring oscillation circuit according to claim 2, wherein the second transistors and the third transistor are formed using the same processes.

4. The ring oscillation circuit according to claim 1, wherein the value of the constant current changes based on fluctuations in the threshold voltages of the inverters.

5. A ring oscillation circuit, comprising:
a ring oscillator in which a plurality of inverters are connected in a ring, and in which a constant current is supplied to each of the inverters; and,
a constant-current circuit which generates the constant current, the constant-current circuit comprises:
a first transistor of a first conduction type, the source of which is connected to a first power supply and the gate of which is connected to the drain;
a second transistor of a second conduction type, connected between the drain of the first transistor and a second power supply;
a third transistor of the first conduction type, the gate of which is connected to the drain of the first transistor, and the source of which is connected to the first power supply;
a fourth transistor of the second conduction type, the drain and gate of which are connected to the drain of the third transistor and to the gate of the second transistor; and,
a fifth transistor of the second conduction type, the drain and gate of which are connected to the source of the fourth transistor, and the source of which is connected to the second power supply.

6. The ring oscillation circuit according to claim 5, wherein each of the inverters comprises a sixth transistor of the first conduction type, the source of which is connected to the first power supply and the gate of which is connected to the gate of the first transistor, and a seventh transistor of the second conduction type, the source of which is connected to the second power supply and the drain of which is connected to the drain of the sixth transistor, and wherein the fifth transistor and the seventh transistor are transistors formed using the same processes.

7. A ring oscillation circuit, comprising a ring oscillator in which a plurality of inverters are connected in a ring and in which a constant current is supplied to each of the inverters and a constant-current circuit which generates the constant current, wherein the constant-current circuit comprises:
a first transistor of a first conduction type, the source of which is connected to a first power supply and the gate of which is connected to the drain;
a second transistor of a second conduction type, the source of which is connected via a resistance to a second power supply and the drain of which is connected to the drain of the first transistor;
a third transistor of the first conduction type, the gate of which is connected to the drain of the first transistor and the source of which is connected to the first power supply; and,
a fourth transistor of the second conduction type, the source of which is connected to the second power supply, the gate of which is connected to a node between the source of the second transistor and the resistance, and the drain of which is connected to the drain of the third transistor and to the gate of the second transistor.

8. The ring oscillation circuit according to claim 7, wherein each of the inverters comprises a fifth transistor of the first conduction type, the source of which is connected to the first power supply, and the gate of which is connected to the gate of the first transistor, and a sixth transistor of the second conduction type, the source of which is connected to the second power supply and the drain of which is connected to the drain of the fifth transistor, and wherein the fourth transistor and the sixth transistor are transistors formed using the same processes.
